(19) United States
(12) Patent Application Publication
(10) Pub. No.: US 2005/0252639 A1
(43) Pub. Date: Nov. 17, 2005

(54) Radiation fin having an airflow guiding front edge

(76) Inventor: Hung-Yi Lin, Taipei (TW)

Correspondence Address: BIRCH STEWART KOLASCH & BIRCH, PO BOX 747, FALLS CHURCH, VA, 22040-0747, US

(21) Appl. No.: 10/929,486

(22) Filed: Aug. 31, 2004

(30) Foreign Application Priority Data
May 14, 2004 (TW) 093207574

(51) Int. Cl. H05K 7/20

(52) U.S. Cl. 165/80.3; 361/704

(57) ABSTRACT

A radiation fin formed by aluminum extrusion or a thin blade arranged in a plurality of number on a radiator to disperse operation heat of electronic equipment includes undulate or bent indented openings formed regularly or irregularly on one or both surfaces of the front edge or top edge of the radiation fin that are abutting the radiation air fan exit to channel airflow generated by the air fan to the bottom of the radiation fin to improve radiator performance.

### BACKGROUND OF THE INVENTION

1. Field of the Invention

The invention relates to a radiation fin arranged in multiple number on a radiator of an electronic equipment that has a plurality of regular or irregular indented openings on the front edge surface close to the radiation fan exit to channel airflow to the bottom of the radiation fin to improve radiator performance.

2. Description of the Prior Art

Integrated circuits (ICs) or other electronic elements usually are fixedly mounted onto a circuit board such as a printed circuit board, then are installed in an almost closed case of an electronic equipment such as a computer host. With the continuous advance in electronic circuit and IC technology, the processing speed of the electronic element is faster. In order to achieve more powerful functions, the electronic elements are packed more densely on the circuit board. As a result, operation temperature of the computer host increases. More efficient radiators are needed to reduce the temperature.

Refer to FIG. 1 for a conventional radiator 9. It includes an air fan 91 and a plurality of radiation fins 92 located thereunder. The radiation fins 92 are mounted onto a conductive base board 93 which is attached to the surface of a computer central processor 4′. The operation temperature of the central processor is transferred through the conductive base board 93 to the radiation fins 92, then is dispelled by the cold wind generated by the air fan 91 so that the operation temperature of the central processor 4′ may be reduced. Theoretically, the radiator structure set forth above could forcefully disperse heat. But wind tunnel tests show that airflow 911 generated by the air fan 91 forms in a bell shape and converges to the outer area of the air fan 91, but almost is absent in the center area. Hence heat in the center portion of the computer central processor 4′ is very difficult to be dispersed by the radiator 9. Moreover, the radiation fins 92 of the radiator 9, whether made of aluminum extrusion or thin blades, usually are very thin. Thus the cooling effect achieved by channeling the airflow from the upper side to the lower side of the radiation fins 92 is limited. As shown in FIG. 1, the bell-shaped airflow 911 generated by the air fan 91 disperses rapidly through two sides after hitting the front edges of the radiation fins 92 if a suitable airflow guiding design does not exist. This operation mode is the main factor why the heat dissipation efficiency of the conventional radiators is not desirable. Many vendors try to increase air fan power to boost the heat dissipation effect. However it is not applicable to the notebook computers that have a small space.

### SUMMARY OF THE INVENTION

The primary object of the present invention is to provide a novel radiation fin for radiators used in computer equipment to solve the problem of the conventional radiators that cannot channel airflow of the air fan to the bottom of the radiator where the temperature is highest and result in poor heat dissipation efficiency. The invention increases the airflow receiving area of the radiation fin so that cool airflow generated by the air fan is channeled through the enlarged area into the bottom of the radiation fin thereby to increase heat dissipation of the heat accumulated on the bottom of the radiator. In practice, the front or top edge of the radiation fin close to the air fan airflow exit is formed with a plurality of regular or irregular indented openings on one surface or both surfaces. The indented openings may be in any shape to increase the area of the radiation fin at the top or front edge that is greater than the thickness of the radiation fin. The area receives the airflow and channels the airflow towards the radiation fin to the bottom of radiation fin where the temperature is highest so that the high temperature heat accumulated there may dispelled to increase heat dissipation efficiency.

According to the feature of the radiation fin of the radiator set forth above, a plurality of indented openings of any shapes are formed on one side or both sides of the front edge on a selected section facing the airflow to channel the airflow to the bottom of the radiation fin to disperse the heat accumulated there. The radiator includes such type of radiation fins can achieve an improved heat dissipation efficiency.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of a conventional radiation fin of a radiator showing airflow directions.

FIG. 2 is a fragmentary perspective view of an embodiment of the radiation fin of the invention.

FIG. 3 is a front view of the radiation fin of the invention showing the airflow direction of the air fan.

FIGS. 4, 5 and 6 are top views of other embodiments of the radiation fin of the invention.

FIG. 7 is a front view of yet another embodiment of the radiation fin of the invention.

FIG. 8 is a fragmentary perspective view of still another embodiment of the radiation fin of the invention.

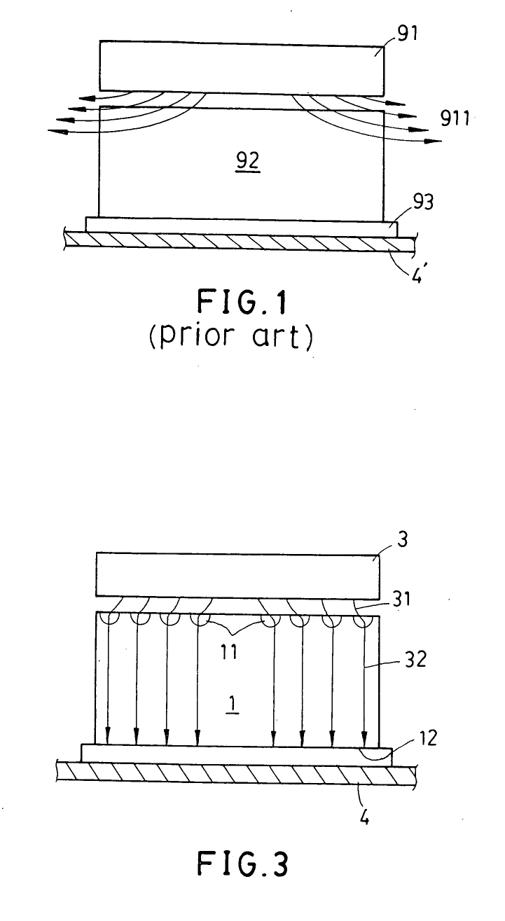

### DESCRIPTION OF THE PREFERRED EMBODIMENTS

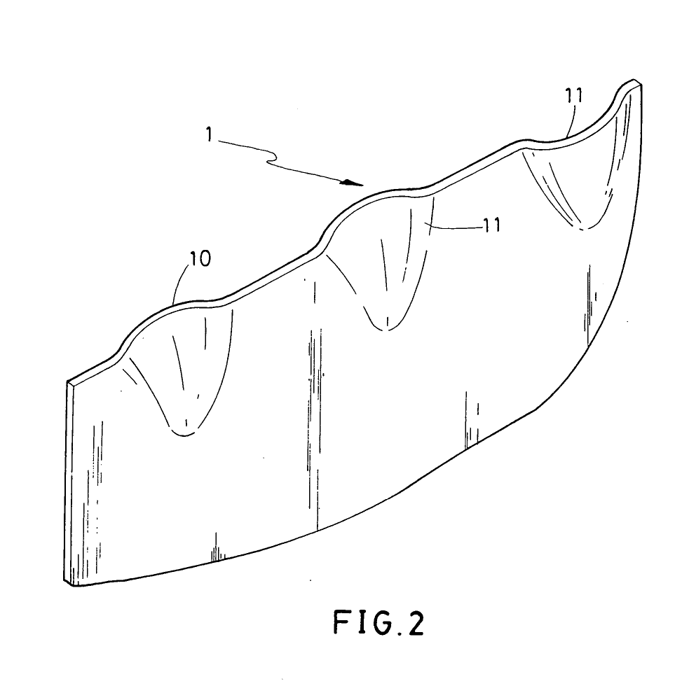

Refer to FIG. 2 for the radiation fin with an airflow guiding front edge of the invention. The radiation fin 1 is formed by aluminum extrusion or a thin blade and is arranged in multiple numbers. Each radiation fin 1 has a front edge or top edge formed or bent to form a plurality of regular or irregular undulate shapes 10 so that one surface or both surfaces of the front edge have a plurality of indented openings 11. The width, depth, height and number may vary depending on the overall area of the radiation fin.

A radiator 2 consists of a plurality of the radiation fins 1 that have the indented openings 111 formed on the front edges. Referring to FIG. 3, the indented openings 11 are located on the front edges of the radiation fins 1 facing the airflow exit of an air fan 3. Thus the bell-shaped airflow 31 leaving the air fan 3 enters the indented openings 11 and changes direction to become a plurality of channeled airflow 32 directing to the bottom 12 of the radiation fin 1. Hence heat generated by a computer CPU 4 that mostly accumulates on the bottom 12 of the radiation fin 1 may be dispelled rapidly by the airflow of the air fan 3.

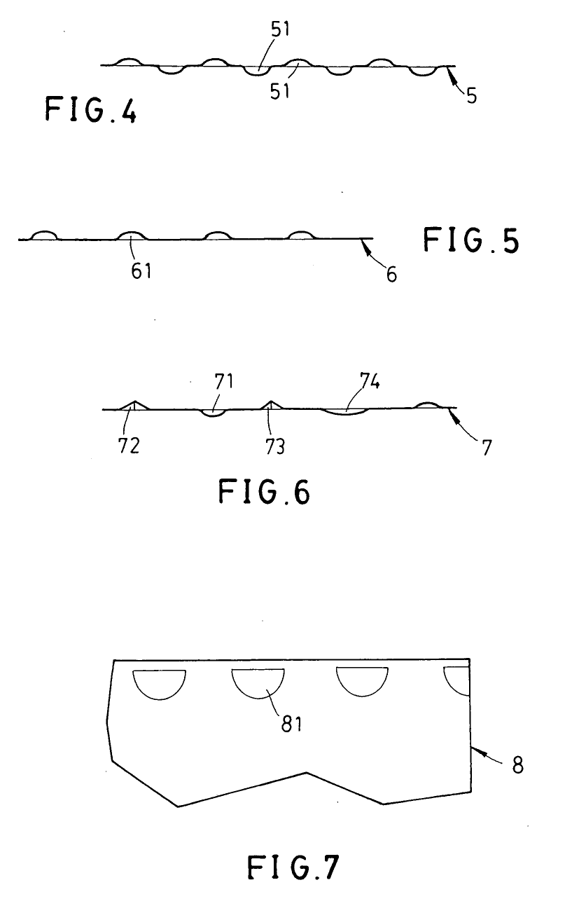

The principle of forming a plurality of indented openings 11 on the front edge of the radiation fin 1 is to increase and alter airflow contact area so that the airflow that would otherwise be dispelled at the upper side of the radiation fin is channeled downwards by the front edge area to the bottom of the radiation fin to improve heat dissipation effect. The indented opening may be formed in a regular or irregular shape. FIG. 4 illustrates a radiation fin 5 has a plurality of regular indented openings 51 formed on two surfaces, while FIG. 5 illustrates a radiation fin 6 with a plurality of regular indented openings 61 formed on one surface. The indented openings may also be irregular and different shapes formed on the front edge of both sides or one side of a radiation fin 7, such as indented openings 71, 72, 73 and 74 shown in FIG. 6.

While the indented openings 11 set forth above are formed on the front edge of the radiation fin 1 in undulate or bent shapes, any shape or structure adopted the technique of the invention that can increase the area of airflow receiving and channel the airflow to the bottom of the radiation fin may also be used. Hence the indented openings may be formed on locations other than the top edge. FIG. 7 depicts another embodiment in which indented openings 81 are close to the top edge of the radiation fin 8.

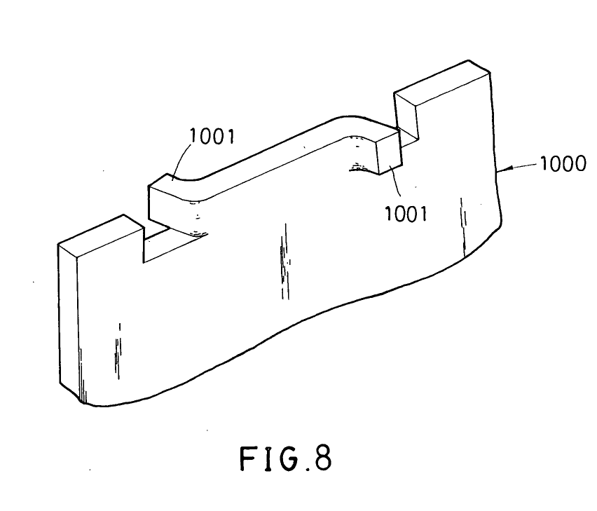

The embodiments previously discussed serve only for illustrative purpose, and are not the limitation of the invention. For instance, the indented openings on the front edge of the radiation fin may be any regular or irregular shape, and be directly formed by extending the front edge of the radiation fin or close to the front edge. FIG. 8 illustrates another embodiment in which the radiation fin 100 has a plurality of jutting blades 1001 bending outwards on the front edge to increase the airflow receiving area of the radiation fin 100 and change airflow direction to the bottom of the radiation fin, thereby to improve cooling effect of the radiation fin.

1. A radiation fin having an airflow guiding front edge arranged on a radiator in a plurality of number for dispersing operation heat of an electronic equipment, comprising:
a plurality of indented openings on the surfaces of a front edge of the radiation fin abutting an airflow exit of a radiation air fan of the radiator.

2. The radiation fin of claim 1, wherein the indented openings are formed on at least one of the surfaces of the radiation fin in a regular manner.

3. The radiation fin of claim 1, wherein the indented openings are formed on at least one of the surfaces of the radiation fin in an irregular manner.

4. The radiation fin of claim 1, wherein the indented openings are formed by extending the front edge of the radiation fin.

5. The radiation fin of claim 1, wherein the indented openings are abutting the front edge of the radiation fin.

6. A radiation fin having an airflow guiding front edge arranged on a radiator in a plurality of number for dispersing operation heat of an electronic equipment, comprising:
a plurality of jutting blades bending outwards from the surfaces of a front edge of the radiation fin abutting an airflow exit of a radiation air fan of the radiator.

7. The radiation fin of claim 6, wherein the jutting blades are formed on at least one of the surfaces of the radiation fin in a regular manner.

8. The radiation fin of claim 6, wherein the jutting blades are formed on at least one of the surfaces of the radiation fin in an irregular manner.

9. The radiation fin of claim 6, wherein the jutting blades are formed by bending the front edge of the radiation fin outwards.

10. The radiation fin of claim 6, wherein the jutting blades are abutting the front edge of the radiation fin.
